(19) United States
(12) Patent Application Publication
(10) Pub. No.: US 2008/0116903 A1
(43) Pub. Date: May 22, 2008

(54) Microwave Sensor For High-Precision Level Measurement In A Pneumatic Spring

(76) Inventor: Richard Koerber, Putzbrunn (DE)

Correspondence Address: ATER WYNNE LLP, 222 SW COLUMBIA, SUITE 1800, PORTLAND, OR, 97201-6618, US

(21) Appl. No.: 11/662,230

(22) PCT Filed: Sep. 9, 2005
(86) PCT No.: PCT/EP05/09727

§ 371 Date: Jul. 24, 2007

(30) Foreign Application Priority Data
Feb. 25, 2004 (DE) DE 102005008880.5
Sep. 9, 2004 (DE) DE 102004043585.5

(51) Int. Cl. G01R 27/04

(52) U.S. Cl. 324/635

(57) ABSTRACT

A device and method are provided for measuring distance in a pneumatic spring with a metal base and cover. The device includes an electrically conductive spring element positioned between a metal base and cover of the pneumatic spring to form a microwave cavity resonator.

### CROSS REFERENCE TO RELATED APPLICATIONS

This application is a filing under 35 USC 371 which claims priority to German application DE 10 2004 043 585.5, filed Sep. 9, 2004, German application 10 2005 008 880.5, filed Feb. 25, 2004 and is based on and claims priority to PCT Application PCT/EP2005/009727, filed Sep. 9, 2005, which are all hereby incorporated by reference in their entirety.

### BACKGROUND OF THE INVENTION

The present invention relates generally to a device for measuring distance and more particularly, to a microwave sensor for measuring distance.

Normally, electronic level regulation systems, in particular for pneumatic suspensions, require so-called level sensors in order to be able to determine and monitor distance. At the present time, sensors are used for determining and monitoring distance which are located outside of the pneumatic spring and are operated separately by means of a deflection rod. This type of sensor is generally exposed to environmental influences and is correspondingly vulnerable. It is also disadvantageous that structural measures are taken which considerably limit the utilisability of pneumatic springs in electronic level regulation systems.

Therefore, a need exists for a level regulation system which has a high degree of measuring precision.

### BRIEF DESCRIPTION OF THE INVENTION

In one embodiment, an electrically conductive spring element is provided for the pneumatic spring, which is preferably integrated into the pneumatic spring. By means of this measure a microwave cavity resonator is formed so that the spacing and the distance between the metal base and cover of the pneumatic spring can be determined. The measuring principle may be based upon determining the resonance frequency of a cylindrical cavity resonator. By means of this measure, and in particular of the electrically conductive spring element, the structural interventions for an electronic level regulation system are minimized.

In another embodiment, a method for measuring distance in a pneumatic spring is provided. The method includes injecting an HF measurement signal into a pneumatic spring, with an electrically conductive spring element being provided between a metal cover and base of the pneumatic spring to form a microwave cavity resonator.

### BRIEF DESCRIPTION OF THE DRAWINGS

FIG. 1 shows a cross-section of a pneumatic spring with a device for measuring distance constructed in accordance with an embodiment of the invention.

FIG. 2 is a mode chart illustrates mode selection in accordance with various embodiments of the invention.

FIG. 3 is a diagram illustrating field distribution in a resonator in an H011 mode in accordance with various embodiments of the invention.

FIG. 4 shows an electromagnetic field simulation of wall currents in accordance with various embodiments of the invention.

FIG. 5 shows the injection and extraction of an electromagnetic measurement signal from a pneumatic spring in accordance with various embodiments of the invention.

FIG. 6 shows the field distribution in the region of the injection from a pneumatic spring in accordance with various embodiments of the invention.

FIG. 7 is a graph that shows the frequency response for the injection and extraction of the measurement signal in accordance with various embodiments of the invention.

FIG. 8 is a graph that shows the relationship between resonance frequency as a function of the resonator level in accordance with various embodiments of the invention.

FIG. 9 is a block diagram of an architecture for determining resonance frequency in accordance with various embodiments of the invention.

FIG. 10 is a block diagram of the architecture of FIG. 9 with a transmitter constructed in accordance with another embodiment of the invention.

### DETAILED DESCRIPTION OF THE INVENTION

The foregoing summary, as well as the following detailed description of certain embodiments of the present invention, will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or random access memory, hard disk, or the like). Similarly, the programs may be stand alone programs, may be incorporated as subroutines in an operating system, may be functions in an installed software package, and the like. It should be understood that the various embodiments are not limited to the arrangements and instrumentality shown in the drawings.

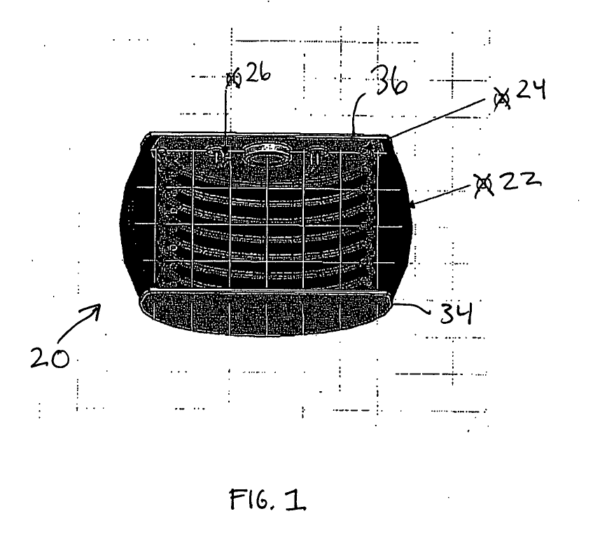

In FIG. 1 a pneumatic spring 20 is shown, bellows 22 of which do not have sufficient conductivity in order to form a microwave resonator with sufficient quality. A coil spring 24, which does not otherwise have any spring force is inserted into the pneumatic spring 20 between a base 34 and a cover 36, and which, with an appropriate wire gauge and incline, forms an almost ideal cavity resonator. A wire loop 26 is provided for injection of an electro-magnetic measurement signal as described below.

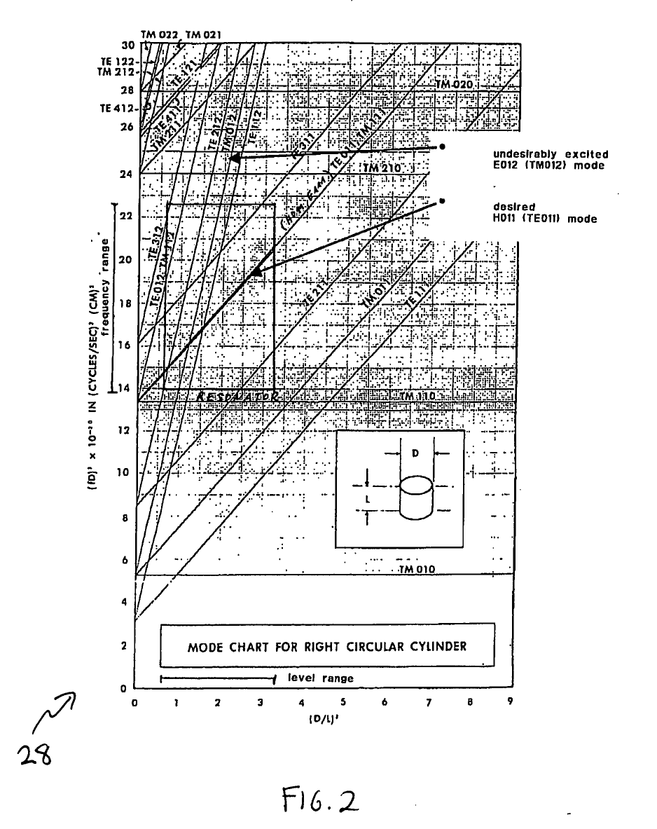

According to the geometry and chosen frequency range, a plurality of wave fields can form so-called modes in a cylindrical cavity resonator, and this is shown correspondingly in the mode diagram 28 according to FIG. 2.

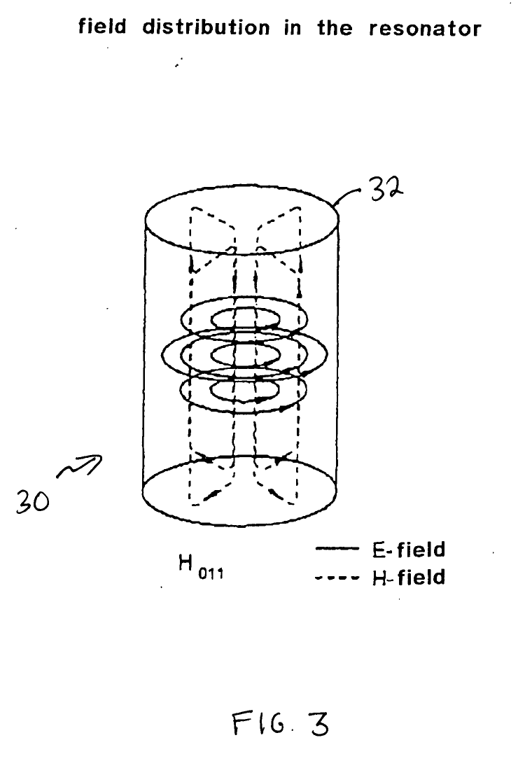

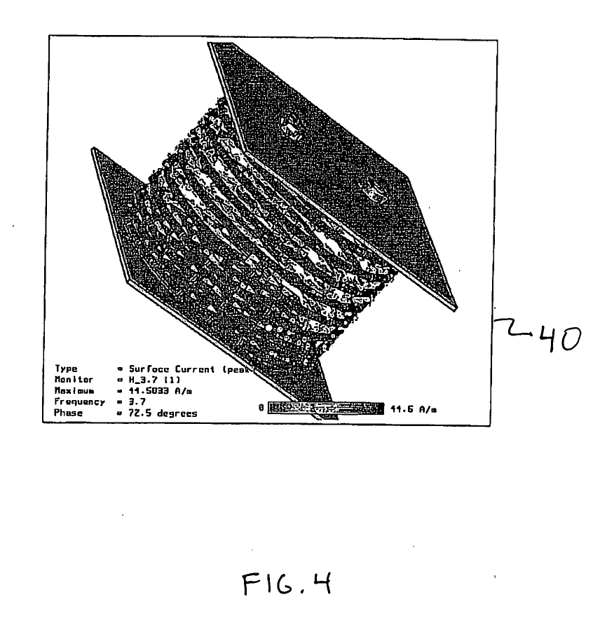

Furthermore, the so-called H011 mode may be used for measuring height and, accordingly, for the level measurement in the pneumatic spring 20. The field distribution 30 is shown in FIG. 3. It is the mode with the highest quality. With the latter, therefore, the highest measuring precision can be achieved. Furthermore, this mode has circular currents exclusively. These wall currents are equal to zero at the peripheral edges of the cylinder 32. This means that the coil spring 20 does not require a good electrical contact with the cylinder covers, and this simplifies the structural technology. Furthermore, the E111 mode which otherwise occurs at the same time, and the wall currents of which extend over the cylinder edge, is suppressed. FIG. 4 shows an electro-magnetic field simulation 40 of the wall currents of the chosen arrangement.

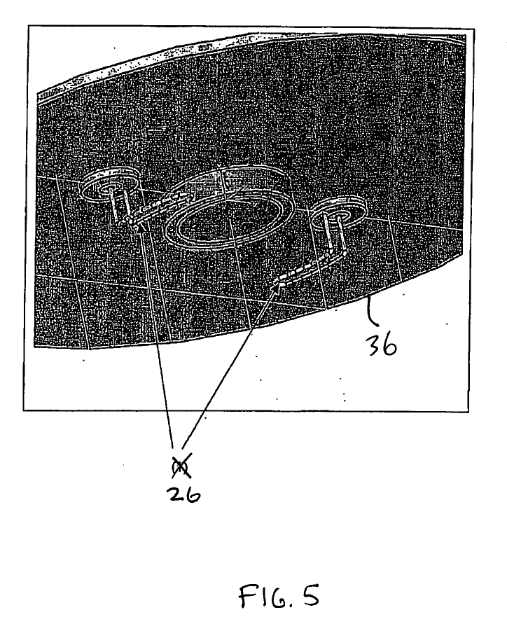

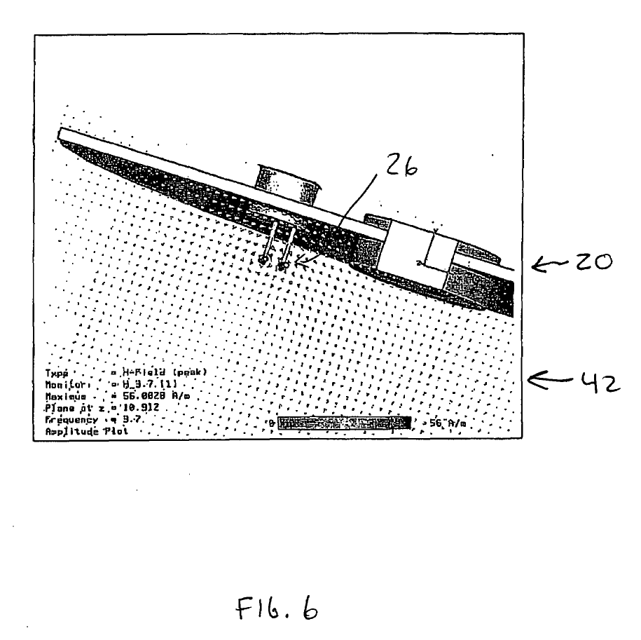

In order to achieve a clear measurement result, further undesired modes are to be suppressed and the H011 mode optimally excited. This is achieved by means of injection and extraction of electromagnetic waves using the wire loop 26 as shown in FIG. 5. According to its field distribution 42 (see FIG. 6), magnetic field lines are excited in the radial direction. The injection is to be arranged such that injection is at the point of the maximum radial component of the magnetic field. The H011 mode is described by the following field equations:

$$\begin{matrix}{E}_{r} = 0 & ( 1 ) \\ {E}_{ϕ} = j ωμ \cdot \frac{D}{2 {j}_{01}^{′}} \cdot {J}_{0}^{′} ( \frac{2 {j}_{01}^{′}}{D} r ) \cdot sin ( \frac{π}{L} z ) & ( 2 ) \\ {E}_{z} = O & ( 3 ) \\ Hr = {H}_{0} \frac{π \cdot D}{2 {j}_{01}^{′} L} \cdot {J}_{0}^{′} ( \frac{2 {j}_{01}^{′}}{D} r ) \cdot cos ( \frac{π}{L} z ) & ( 4 ) \\ H ϕ = 0 & ( 5 ) \\ {H}_{2} = {H}_{0} \cdot {J}_{0} ( \frac{2 {j}_{01}^{′}}{D} r ) \cdot sin ( \frac{π}{L} z ) & ( 6 )\end{matrix}$$

with j′₀₁=3.832 1. zero position for deducing the Bessel function 0. order J′₀

J₀ and J′₀=−J₁ Bessel functions

D Diameter of the resonator

L Length of the resonator

As one can see for the formula for H, the radial dependency is given by the factor

$${J}_{0}^{′} ( \frac{2 {j}_{01}^{′}}{D} r ) .$$

The maximum of J′₀ (x) is achieved with x=1.841. The resolution of the condition

$$\frac{2 {j}_{01}^{′}}{D} r = 1.841 \qquad ( 7 )$$

according to r gives

$$\_r = 0.48 \cdot \frac{D}{2} \qquad ( 8 )$$

The injection is therefore ideally to be applied at the distance r from the centre point of the cover 36.

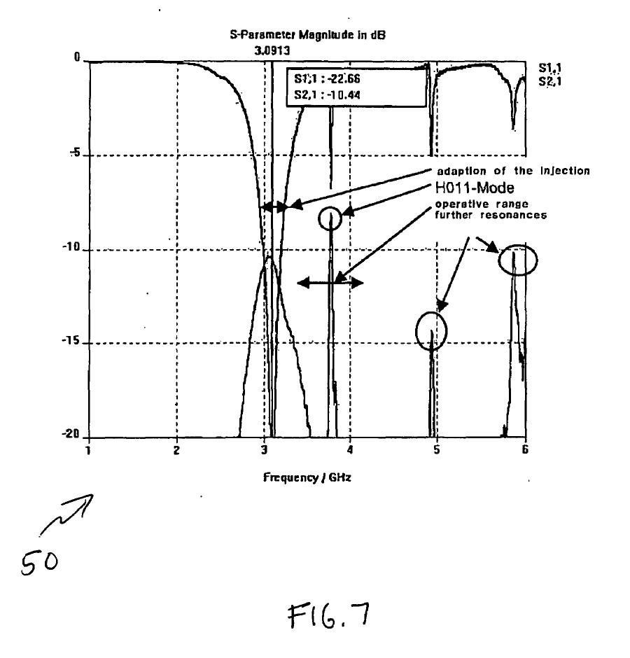

Furthermore, the injection is to be designed such that in the operative frequency range the injection only connects weakly so that the quality of the resonator is not reduced. FIG. 7 shows a graph 50 of the frequency response of the adaptation of the injection. The region of the adaptation is set by the length of the wire loop 26. With the coil spring 24 chosen, the operative frequency range is between 3.4 and 4.3 GHz, whereas the length of the injection is chosen so that the injection is adapted to the region of around 3 GHz.

Furthermore, the coil spring 24 is to be designed so that the radiation of the electromagnetic wave becomes minimal and does not exceed the limit value established, for example, by the regulatory authorities.

The resonance frequency of the H011 mode in the ideal cylindrical cavity resonator, which is completely filled with loss-free dielectricum, can be calculated according to the following formula:

$$\_r = 0.48 \cdot \frac{D}{2} \qquad ( 8 )$$

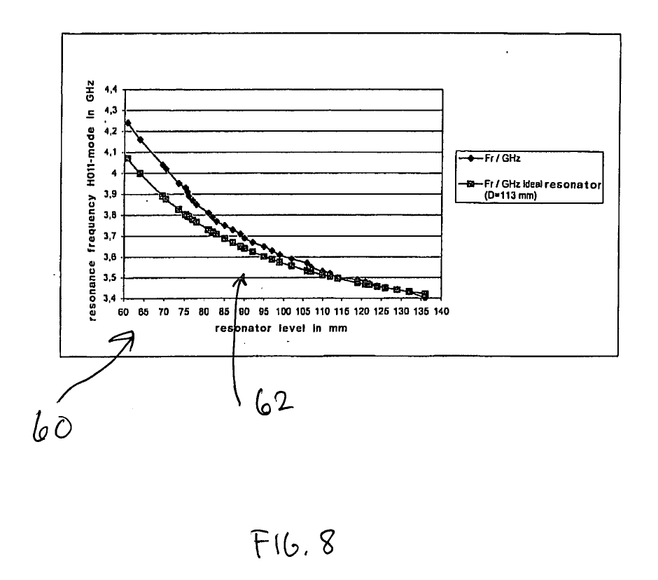

FIG. 8 is a graph 60 that shows the course of the resonance frequency as a function of the resonator height for the ideal resonator and the measured value of a coil spring 24 with the same inner diameter.

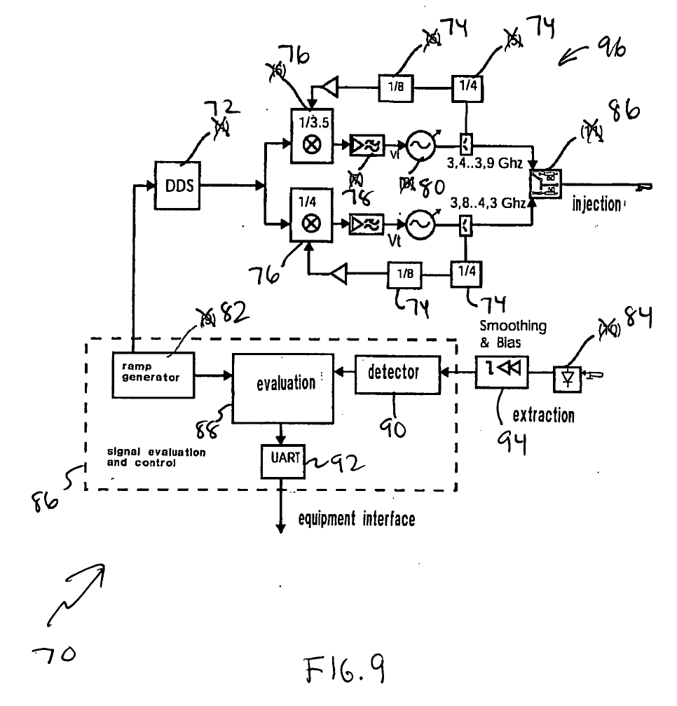

In order to measure the height of the resonator, the resonance frequency of the resonator must therefore be determined. This may be implemented using the architecture 70 shown in FIG. 9.

Using a direct digital synthesizer (DDS) 72 and a phase-locked loop (PLL) including a frequency divider 74, a phase discriminator 76 and a loop filter 78, the frequency of an oscillator 80 is set to be stable. A ramp generator 82 prompts the DDS 72 to tune the frequency linearly. As soon as a detector 84 engages with the resonance point, the frequency tuning is held and the current frequency value of the DDS 72 is read out. The height of the resonator and so the level of the pneumatic spring 20 (shown in FIG. 1) can therefore be determined by means of the characteristic curve 62 shown in FIG. 8. In the chosen example, the oscillator frequency must be set to 10 MHz in order to achieve distance measurement precision of 1 mm.

It should be noted that a signal evaluation and control unit 86 may include the ramp generator 82, and evaluation unit 88, a detector 90 and a universal asynchronous receiver/transmitter (UART) 92, which outputs to an equipment interface. A smoothing and bias component 94 also may be provided in connection with the detector 84.

In the present example, the lift of the pneumatic spring 20 is 75 mm. This means that a frequency range of between 3.4 and 4.3 GHz must be covered. Oscillators may not have such a large tuning width. Accordingly, a second oscillator may be connected by means of an HF switch 86 for the upper part of the frequency range.

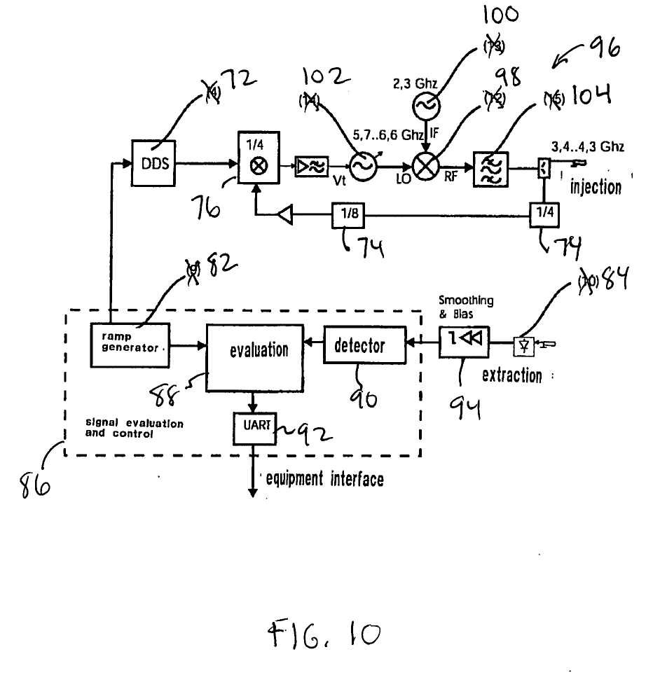

In another embodiment, the transmitter 96 can also be formed by the architecture shown in FIG. 10. A down-mixer 98 is activated on the intermediate frequency side of a 2.3 GHz oscillator 100, whereas on the local oscillator side there is a higher-frequency oscillator 102. Because the band width of the oscillators is in proportion to the center frequency, this higher-frequency oscillator can cover the required band width of 1.1 GHz. On the RF output of the mixer 98, the desired transmission frequency is then set. However, the mixer produces many further undesired co-transmissions, which are suppressed by a band-pass filter 104.

Thus, an electrically conductive spring element is provided for measuring distance in, for example, a pneumatic spring. The spring element is positioned between a base and cover of the pneumatic spring to form a microwave cavity resonator.

Moreover, the spring element may be in the form of a coil spring which, with an appropriate wire gauge and incline forms an almost ideal cavity resonator. It should be noted that the coil spring is otherwise provided without any spring force for the pneumatic spring and is inserted into the pneumatic spring. Due to the geometric properties of a coil spring, a cylindrical cavity resonator is therefore formed in which a plurality of wave fields corresponding to the chosen frequency range form so-called modes.

Injection into the cavity resonator may excite the H011 mode. Due to the field distribution, the mode is therefore excited with the highest quality and the highest measuring precision is achieved. Furthermore, this mode has circular currents exclusively so that at the peripheral edges of the cylindrical form, i.e. cylinder, produced by the cavity resonator, these wall currents are equal to zero. This means, for example, that when using a coil spring, a good electrical contact with the cylinder cover or base is not required, due to which the structural technology is simplified. Furthermore, the E111 mode which otherwise occurs at the same time, and the wall currents of which extend over the cylinder edge, is suppressed.

With the help of a direct digital synthesiser and a phase regulation loop, the frequency of an oscillator required in order to determine the resonance frequency is set to be stable. If coupling is implemented by means of a wire loop, the structural measures are kept simple.

In order to achieve an optimal measuring result with regard to determining the resonance frequency, if the measurement signal may be provided a distance R away from the center point of the cylinder cover according to the formula R=0.48.×(D/2), D being the diameter of the resonator.

It is to be understood that the above description is intended to be illustrative, and not restrictive. For example, the above-described embodiments (and/or aspects thereof may be used in combination with each other. In addition, many modifications may be made to adapt a particular situation or material to the teachings of the invention without departing from its scope. While the specific components and processes described herein are intended to define the parameters of the various embodiments of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein”. Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 USC § 112, sixth paragraph, unless and until such claim limitations expressly use the phrase “means for” followed by a statement of function void of further structure.

1. A device for measuring distance in a pneumatic spring with a metal base and cover, the device comprising:
an electrically conductive spring element positioned between a metal base and cover of the pneumatic spring to form a microwave cavity resonator.

2. The device according to claim 1, wherein the spring element comprises a metal coil spring.

3. The device according to claim 1 wherein an injection of an electro-magnetic measurement signal into the microwave cavity resonator is excited using an H011 mode.

4. The device according to claim 1 further comprising a direct digital synthesizer with a phase regulation loop configured to detune an oscillator and determine a resonance frequency.

5. The device according to claim 1 further comprising at least one wire loop configured to inject an electro-magnetic measurement signal into the microwave cavity resonator.

6. The device according to claim 1 further comprising at least one wire loop configured to inject an electro-magnetic measurement signal into the microwave cavity resonator, and one wire loop configured to extract an electro-magnetic measurement signal from the microwave cavity resonator.

7. The device according to claim 1 wherein an injection of an electro-magnetic measurement signal into the microwave cavity resonator is provided at a distance (R) away from a center point of the cover in accordance with:
R=0.48.×(D/2);
D being the diameter of the resonator.

8. A method for measuring distance in a pneumatic spring, the method comprising:
injecting an HF measurement signal into a pneumatic spring, with an electrically conductive spring element being provided between a metal cover and base of the pneumatic spring to form a microwave cavity resonator.

9. The method according to claim 8, wherein the spring element comprises a metal coil spring.

10. The method according to claim 8 further comprising exciting the microwave cavity resonator in an H011 mode.

11. The method according to claim 10 wherein injecting is provided in a region of a maximum field strength of the H011 mode.

12. The method according to claim 8, wherein the injecting provided a distance (r) away from a center point of the cover in accordance with:
R=0.48.×(D/2)
D specifying the diameter of the resonator.

13. A metal spring element for forming a microwave cavity, the metal spring element comprising:
a metal coil spring configured to determine the distance between a cover and a base of a pneumatic spring using resonance frequency properties of the microwave cavity.

14. (canceled)
